(19) United States
(12) Patent Application Publication
(10) Pub. No.: US 2017/0075036 A1
(43) Pub. Date: Mar. 16, 2017

(54) WEATHER CONDITION INFORMATION BASED ON MAGNETOMETERS

(71) Applicant: Nokia Technologies Oy, Espoo (FI)

(72) Inventors: Mikhail Pikhletsky, Moscow (RU); Ilya Gartseev, Moscow (RU); Ilia Safonov, Moscow (RU)

(21) Appl. No.: 15/310,563

(22) PCT Filed: May 13, 2015
(86) PCT No.: PCT/IB15/53538

§ 371 Date: Nov. 11, 2016

(30) Foreign Application Priority Data
May 14, 2014 (RU) 2014119259

(51) Int. Cl. G01W 1/14; G01R 33/02

(52) U.S. Cl. CPC G01W 1/14; G01R 33/02; G01W 2203/00; G01W 2001/006

(57) ABSTRACT

Weather related data is collected using a magnetic sensor of a mobile device. The mobile device may be within a moving motor vehicle. The magnetic sensor may detect a magnetic field that is generated or otherwise affected by the operation of motor driving one or more windshield wipers. The mobile device, or a server in communication with the mobile device, may perform analysis of the windshield wiper data and generate weather message based on the analysis.

### FIELD

The following disclosure relates to weather condition information based on magnetometers, or more particularly, windshield wiper detection for weather condition information.

### BACKGROUND

Current weather information is important for everyone. The television weather forecast and weather forecasts in print media give only a general picture of the weather. These forecasts typically list predicted high temperatures, low temperatures, and a chance of precipitation. The chance of precipitation may be associated with a wide time frame (e.g., morning, afternoon, or night).

In recent years, websites and other Internet resources such as mobile applications have shortened the time frame for weather reports. Websites may provide forecasts broken down hour by hour, including a chance of precipitation for each hour. However, at best the forecasts are defined by city. The weather forecast for one part of the city is the same as another part of the city even though differences will occur in the actual weather.

Challenges remain in providing weather forecasts that are more granular in both timing for when the particular weather event will occur and the location of the particular weather event.

### SUMMARY

Weather related data is collected using a magnetic sensor of a mobile device. The mobile device may be within a moving motor vehicle. The magnetic sensor may detect a magnetic field that is generated or otherwise affected by the operation of motor driving one or more windshield wipers. The mobile device, or a server in communication with the mobile device, may perform an analysis of the windshield wiper data and generate weather message based on the analysis.

### BRIEF DESCRIPTION OF THE DRAWINGS

Exemplary embodiments of the present invention are described herein with reference to the following drawings.

FIG. 1 illustrates an example system for weather data collection and reporting.

FIG. 2 illustrates another example system for weather data collection and reporting.

FIGS. 3A and 3B illustrate example displays of weather data.

FIG. 4 illustrates an example display of weather data and traffic data.

FIG. 5 illustrates an example system for weather data collection.

FIG. 6 illustrates an example flowchart for detecting wiper spikes in sensor data.

FIGS. 7A and 7B illustrate example magnetic field data.

FIGS. 8 and 9 illustrate example magnetic field data for multiple axes.

FIG. 10 illustrates an exemplary server of the system of FIG. 1.

FIG. 11 illustrates an example flowchart for weather data collection.

FIG. 12 illustrates an exemplary mobile device of the system of FIG. 1.

FIG. 13 illustrates another example for weather data collection.

### DETAILED DESCRIPTION

From larger megapolises to smaller towns, roadways are covered with a huge amount of vehicles. The coverage may be dense even in night hours. The vehicles may be harnessed as a source of information about the weather in specific areas of the city. The vehicles have a few elements whose operation is indirectly related to the weather conditions. One example includes windshield wipers. The wipers are usually turned on when it is raining or snowing, or when there is mud, puddles, or slush in the road that splashes onto the windshield. Moreover, the speed of wipers depends on how strong the rain or the snow is. The information about wipers switched on and the speed of wipers could determine road conditions for a particular location.

In addition, the majority of drivers have portable communication devices such as mobile phones capable of transmitting information over the mobile network connections. The detection of wipers movement, from which an estimation of wiper speed and frequency may be calculated, may be derived from the output of magnetometers in the portable devices. This means that current weather conditions in a particular location can be transmitted to external servers for accumulation and further processing. The accumulation and processing of such data from multiple vehicles can represent a reliable picture of the road conditions for the particular location.

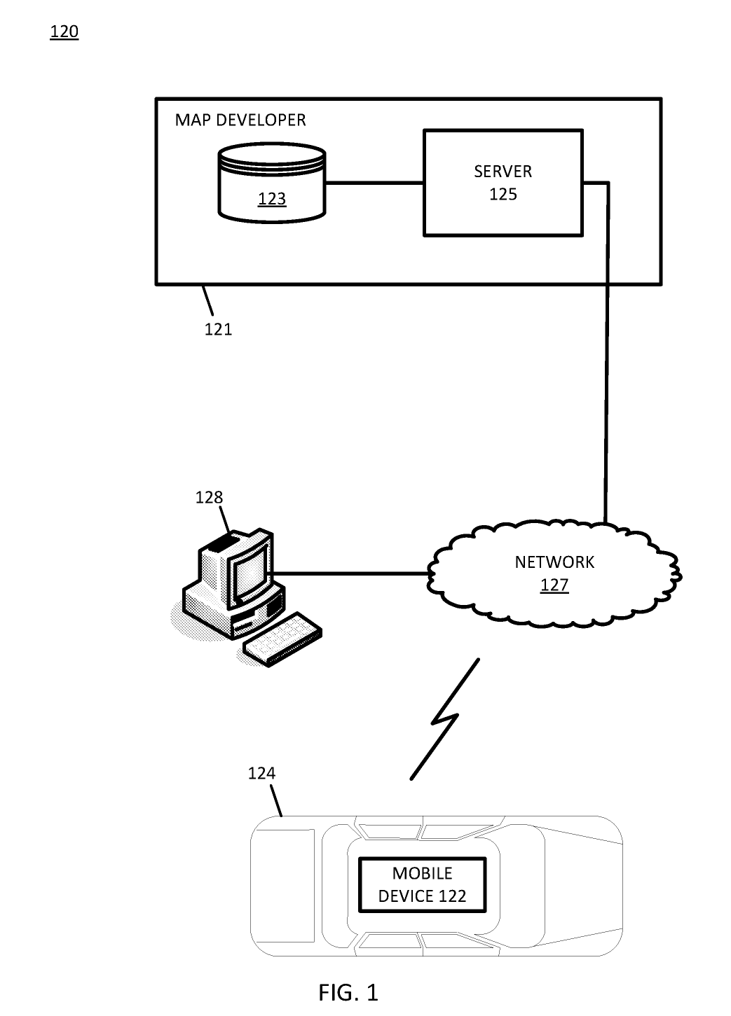

FIG. 1 illustrates an example system 120 for weather data collection and reporting. The system 120 includes a developer system 121, one or more mobile devices 122, a workstation 128, and a network 127. Additional, different, or fewer components may be provided. For example, many mobile devices 122 and/or workstations 128 connect with the network 127. The developer system 121 includes a server 125 and a database 123. The developer system 121 may include computer systems and networks of a system operator.

The mobile device 122 may be carried by a vehicle 124. The mobile device 122 may generate sensor data based on a weather related device on the vehicle 124. The weather related device may be one or more wipers. The wipers may be any combination of windshield wipers, rear glass wipers, mirror wipers, or headlight wipers.

The sensor data may be generated by a magnetometer, which may be a compass or another type of magnetic sensor. The magnetometer is configured to measure magnetic fields (e.g., the magnetic field of the earth). The magnetic fields may include vector quantities having a magnitude measured in Gauss or Tesla and a direction. The magnetometer may include a single axis that measures the magnetic field in one direction or multiple (e.g., X direction, Y direction, Z direction) axes that measure the magnetic field in multiple directions.

The one or more wipers may be powered by a motor (e.g., DC motor) that generates a magnetic field. The magnetic field of the wiper may be detected by the magnetometer either alone or in combination with other magnetic fields such as the magnetic field of the Earth. The motor may move one direction then another direction, which causes a component of the magnetic field to change directions.

The mobile device 122 may send the sensor data to the server 125. The mobile device 122 or the server 125 may perform an analysis on the sensor data. The analysis may involve comparing the magnetic field to a threshold, a slope of the magnetic field to a threshold, or another comparison.

A weather message may be generated based on the analysis. The weather message may be a message to another mobile device describing a state of the weather (e.g., precipitation, no precipitation) inferred from the analysis of the sensor data. The weather message may update a weather database 123.

The mobile device 122 may be a mobile device such as a smart phone, a mobile phone, a personal digital assistant (“PDA”), a tablet computer, a notebook computer, a navigation device, and/or any other known or later developed portable or mobile computing device.

The optional workstation 128 is a general purpose computer including programming specialized for the following embodiments. For example, the workstation 128 may receive user inputs for the thresholds used to judge the magnetic fields. The workstation 128 may receive data based on the type of vehicle, type of windshield wiper drive system, or type of mobile device 122, any combination of which may impact the thresholds.

The developer system 121, the workstation 128, and the mobile device 122 are coupled with the network 127. The phrase “coupled with” is defined to mean directly connected to or indirectly connected through one or more intermediate components. Such intermediate components may include hardware and/or software-based components. The computing resources may be divided between the server 125 and the mobile device 122.

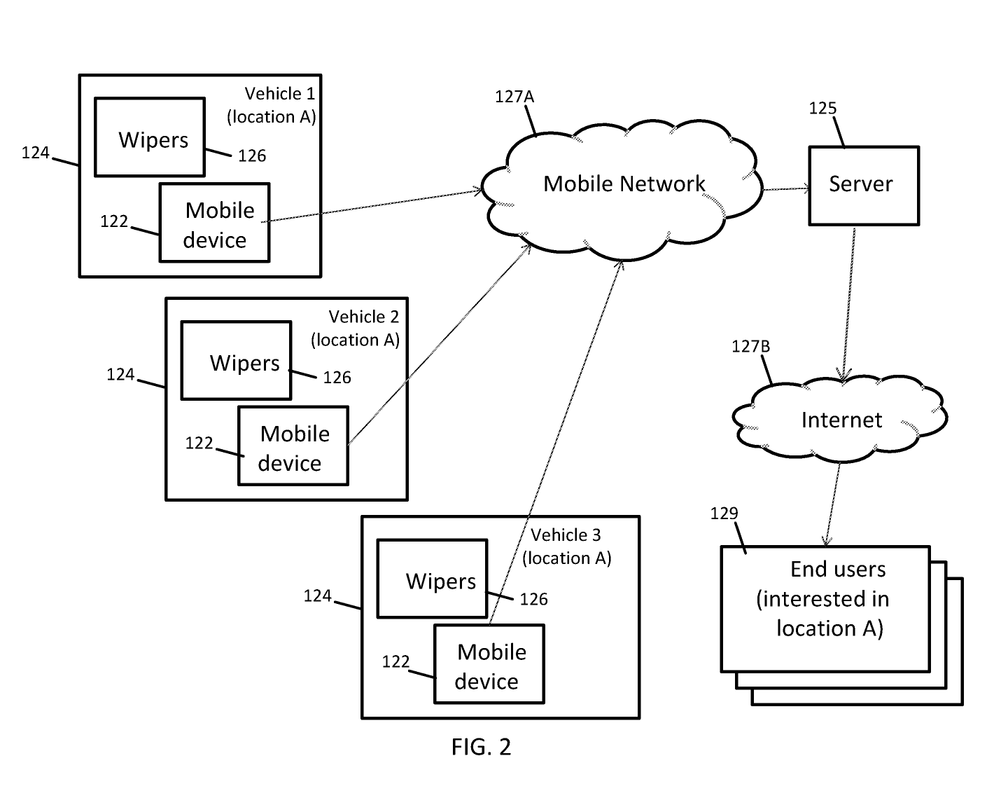

FIG. 2 illustrates another example system for weather data collection and reporting. The system includes multiple vehicles 124, illustrated as vehicle 1, vehicle 2, and vehicle 3. Each vehicle 124 may include mobile device 122 and one or more wipers 126. The mobile devices 122 may communicate with the server 125 through a mobile network 127A, which may be a cellular data network. The server 125 may communicate with other users via the Internet 127B.

Each of the mobile devices 122 may include position circuitry configured to generate location data according to the geographic location of the multiple vehicles 124. The location data may be coupled with the sensor data (e.g., windshield wiper data). Examples for the location data may be a longitude value and a latitude value, a path segment, or a path segment and a position along the path segment. Examples for the sensor data may be on or off, an intensity value, or a speed value.

The server 125 may aggregate the location data and the sensor data for multiple vehicles according to the location data. For example, the multiple vehicles 124 in FIG. 2 have been identified at being at or near the same location (e.g., location A). The locations may be defined by a geographic area, such as a center point and a radius (each geographic area is a location). The locations may be defined by path segment (each path segment is a location).

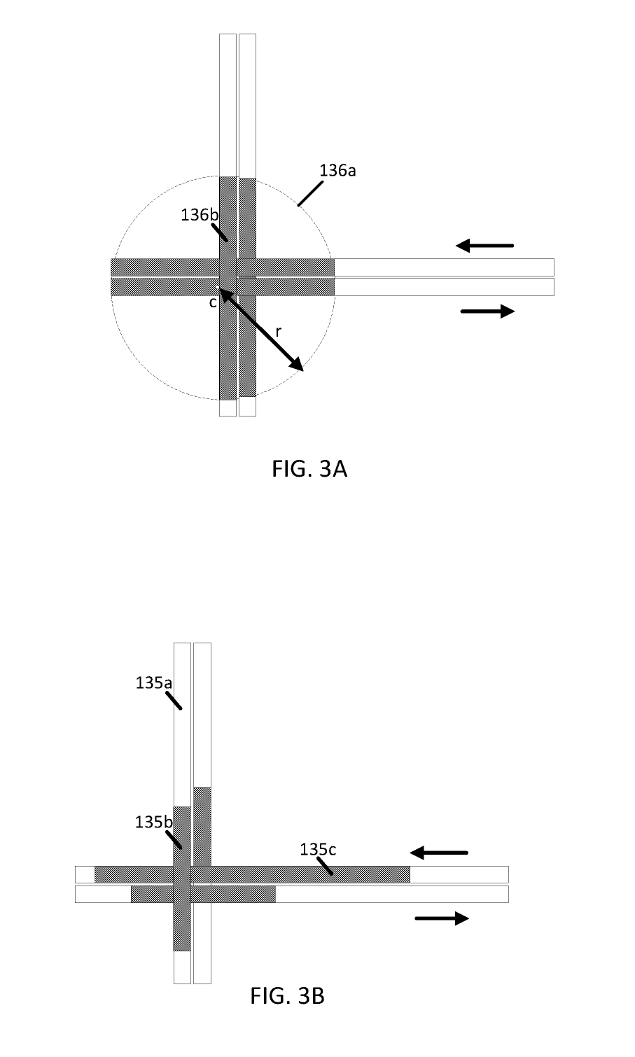

FIG. 3A illustrates an example display of weather data. Two path segments (or four path segments) meet at an intersection. A location is illustrated near the intersection by a circle 136a defined by radius (r) and a center point (c). The path segments 136b within the circle 136a are shaded to illustrate the weather at the location. The shading of the path segments 136a may indicate that it is raining with the circle 136a.

FIG. 3B illustrates another example display of weather data in which the location is defined by subsection of path segment (each sub-segment is a location). The example of FIG. 3B illustrates a region 135a, representing one or more subsections, in which none or few vehicles are reporting the precipitation or other weather condition. The regions 135b and 135c represent one or more subsections in which vehicles are reporting the precipitation or other weather condition. The regions 135b and 135c may be sized differently because they include a different number of subsections or because they include subsections of different sizes.

The size of the subsection of the path segment may be a function of the density of vehicles on the path segment. As more vehicles are present, more data points for the sensor data exist, and the path segments may be divided into smaller subsections.

The size of the subsection of the path segment may be a function of the functional class of the path segment. Example functional classes include arterial roads, collector roads, and local roads. The functional classifications may be related to speed. An arterial road maybe the fastest mode of travel between two points. Collector roads connect arterial roads to local roads. Collector roads are slower than arterial roads. Local roads are accessible to individual homes and business. Local roads are the slowest type of road. Path segments with arterial roads, with vehicles moving faster, may be assigned larger subsections. Path segments for collector roads, with vehicles moving slower, may be assigned smaller subsections. Path segments for local roads, which vehicles moving the slowest, may not be divided into subsections at all.

The server 125 may identify multiple vehicles in a location. For example, the three vehicles 124 are in the same location. The server 125 may analyze the sensor data to determine a representative value for the location. The sensor data may be averaged across the vehicles in the same location. The server 125 may identify one or more outliers (e.g., drop the lowest value, drop the highest value) for the intensity of sensor data. When the sensor data describes whether wiper status is on or off, the server 125 may determine which status is in the majority.

Alternatively, the server 125 may determine whether the number of on wipers in the location exceeds a predetermined quantity (e.g., 10) or predetermined percentage threshold (e.g., 70%) of turned-on wipers out of the total detected wipers. The server 125 may compare the number of wipers in the location to multiple thresholds. If the number of operating wipers is higher than a low threshold (e.g., 2 or 30%) but less than a high threshold (e.g., 10 or 70%), the server 125 identifies low intensity precipitation, and if the number of operating wipers is greater than the high threshold, the server 125 identifies a high intensity precipitation. The low intensity versus high intensity may also be based on the speeds of the wipers.

The server 125 may assign the representative value to the location and distribute the representative value to other mobile device 122 that are traveling at the location or near the location. In the alternative to the representative value for the sensor data, which may include an indication that windshield wipers are being used at the location, the server 122 may determine a weather message (e.g., light precipitation, heavy precipitation) based on the sensor data. The type of precipitation (e.g., rain, sleet, snow) may be included in the weather message and based on the ambient temperature.

The server 125 may distribute the representative value to mobile devices 122 that have accessed routes that include the location. The server 125 may distribute the representative value to mobile devices that have requested a route including the location or have specifically requested the weather message. The weather message includes a map including the location. The map may include multiple locations based on their respective weather message (color coded for precipitation versus no precipitation or by the intensity of precipitation).

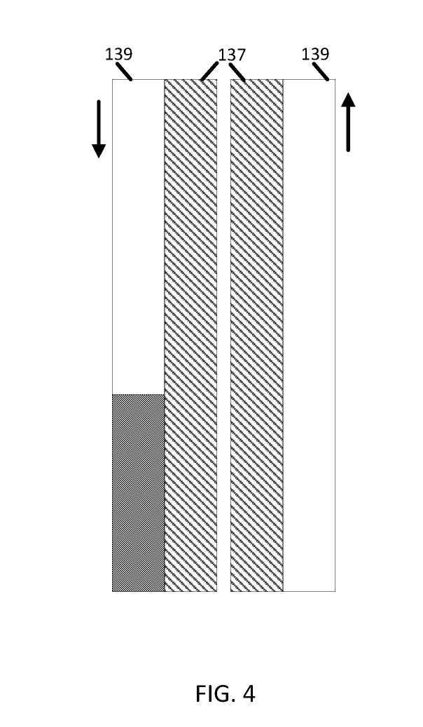

FIG. 4 illustrates an example display of weather data in combination with traffic data. The path segments of a map may be divided into a traffic portion 139 and a weather portion 137. The graphical representation of each direction of travel of the path segment may be separately illustrated to include indicia for the weather and indicia for the traffic. In one example, as shown by weather portion 137, the weather may be the same for both directions of traffic but, as shown by traffic portion 139, the traffic levels may be different. Multiple path segments may be displayed having independent indicia for traffic and weather.

The weather portion 137 may be defined by the sensor data describing the weather (e.g., windshield wiper data). The traffic portion 139 may also be defined according the speed of vehicles, as received by the server 125 or derived from the change in location data received at the server 125. Alternatively, the traffic data may be received from a broadcasting service such as traffic message channel (TMC) or another addressing scheme to map traffic conditions to path segments. The term TMC may refer to the traffic reporting format or protocol, or the term TMC may refer to a specific path segment. The TMC may include a global identification value that universally identifies the path segment.

The traffic conditions for a path segment may be determined by tracking probes (e.g., vehicles with position enabled devices). The traffic conditions may be calculated using average speed, for example, as calculated from the entry and exit times of a probe as it travels the path segment and the length of the path segment. The resulting average speed is applied uniformly as the traffic condition for the entire path segment. However, the path segment may include multiple traffic conditions. For example, depending on the length of the path segment, the traffic near the beginning of the path segment may be at one speed, and the traffic near the end of the path segment may be at another speed. In another example, the traffic condition may vary between lanes. An obstacle or another traffic incident may impede traffic one lane but not in another lane. An exit lane may experience congestion because of traffic backing up at the exit or because of a traffic condition on the downstream path segment connected to the exit lane.

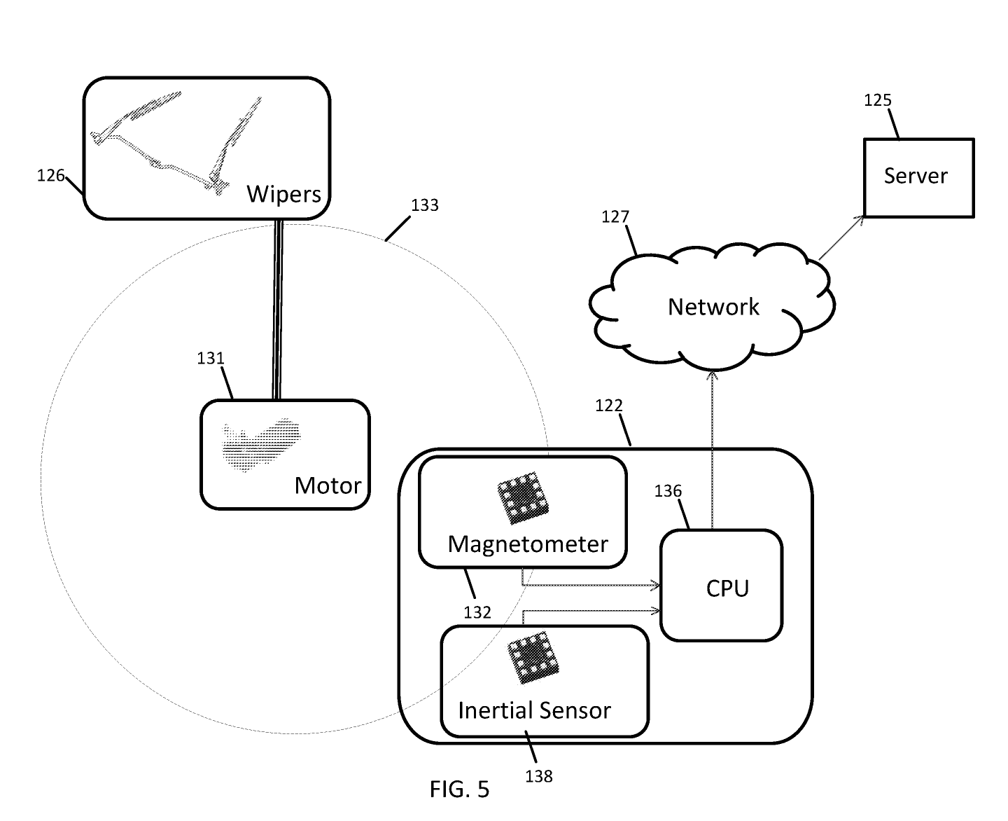

FIG. 5 illustrates an example system for weather data collection. The wipers 126 are physically coupled to one or more motors 131. The physical connection may include a drive rod, a drive gear, rack and pinion, or other mechanism for transferring mechanical force from the motor 131 to the wipers 126. The motor 131 may change direction (e.g., clockwise to counterclockwise and vice versa) in order to drive the wipers 126 in different across a surface (e.g., windshield, read glass, or mirror).

The drive gear may include a worm gear that multiplies (e.g., by 50) the torque of the motor 131 to a high force applied to the wipers 136. Two or more windshield wipers may be driven by independent motors 131. Alternatively, one motor 131 may drive multiple windshield wipers by driving a gear that rotates a cam for oscillating a linkage rod connected to the multiple windshield wipers. Thus, the motor 131 may rotate in a single direction but drive the wipers 126 back and forth in two directions.

The operation of the motor 131, either in one direction or by changing direction, alters or generates a magnetic field 133 in the vicinity of the motor 131. The magnetic field may be detected by magnetometer 132 and data representing the magnetic field is sent from the magnetometer 132 to the CPU 136. The CPU 136 may process the data representing the magnetic field or send the data representing the magnetic field to server 125 for processing via network 127.

In one example, the magnetometer 132 is continuously collecting magnetic field data. However, in other examples the magnetometer 132 is triggered to collect data based on the speed or orientation of the mobile device 122. In one example, the position circuitry tracks the location and speed of the mobile device 122, and the magnetometer 132 collected magnetic field data when the mobile device 122 is traveling above a threshold speed (e.g., 10 miles per hour, 30 miles per hour, or another value). In one example, the position circuitry includes one or more inertial sensors 138 (e.g., accelerometers, gyroscopes, or another sensor) that track the movements and vibration patterns of the mobile device 122 by sending movements and vibration data to the CPU 136.

Based on the movement data, the CPU 136 may determine that the mobile device 122 is located inside a vehicle when the mobile device 122 makes movements in a manner typical of residing in a vehicle. In one example, the analysis includes a general scheme for human activity recognition that can be used for detection in-vehicle state. Signals from the 3-axes accelerometer may be sampled with frequency from 25 to 40 Hertz. Raw signals of 3-axis accelerometer are processed by a low-pass filter in order to suppress high-frequency noises (e.g. finite impulse response filter with convolution kernel [1 1 1 1 0 0 0] may be used).

Smoothed signals output from the filtering may be analyzed for features extraction. For example, signals are partitioned on frames (or time windows). For instance, the frame size may correspond to 7 seconds. The frames may be overlapped or non-overlapped. The feature set [Fi] may be calculated for each frame. Features can be calculated in time-domain and frequency domain.

Example time-domain features derived from magnitude (s) signal may include:

$${s}_{i} = \sqrt{{x}_{i}^{2} + {y}_{i}^{2} + {z}_{i}^{2}} , and$$

$$mean = \frac{1}{n} {\sum }_{i = 1}^{n} {s}_{i} ,$$

where n is number of samples in frame, x, y and z are channels of 3-axes accelerometer;

$$variance = \frac{1}{n} {\sum }_{i = 1}^{n} {( {s}_{i} - mean )}^{2} , \\ average absolute difference = \frac{1}{n} {\sum }_{i = 1}^{n} \vert {s}_{i} - mean \vert , \\ mean crossing rate = \frac{1}{n - 1} {\sum }_{i = 1}^{n - 1} CR ( {s}_{i} , {s}_{i + 1} ) , where$$

$$CR ( a , b ) = \{ \begin{matrix}1 \text{:} & a \times b < 0 \\ 0 \text{:} & otherwise\end{matrix} .$$

Also quantiles Q₁₀, Q₂₅, Q₅₀, Q₇₅, Q₉₀ and interquartile difference IQD=Q₇₅−Q₂₅ are calculated for magnitude s. Signal Magnitude Area (SMA) is calculated from x, y and z channels as:

$$s m a = \frac{1}{n} {\sum }_{i = 1}^{n} ( \vert {x}_{i} \vert + \vert {y}_{i} \vert + \vert {z}_{i} \vert ) .$$

A fast Fourier transform (FFT) may be applied for magnitude of signal transformation to frequency domain. In the frequency domain energy, entropy and peak position may be calculated for various portions of the spectrum and/or sub-bands. Features for each frame are transferred to block of classifiers. A machine learning algorithm (e.g., Adaboost, neural network, or another example) may identify states such as “walking,” “in vehicle,” “stationary” and “other” for current frame. The machine learning algorithm may utilize a voting scheme to identify the state.

In other alternatives, further sequences of states for consecutive frames are processed by classifier based on Hidden Markov Model (HMM) or another probabilistic model or state machine. The output of the HMM-classifier may be a function of recognized activities (Ci) and a confidence levels (Li) for consecutive frames.

Based on any combination of sampling, filtering, or classification of the output of the inertial sensor 138, the CPU 136 may determine that the mobile device 122 is located inside a vehicle and generate a trigger command. In response to the trigger command, the CPU 136 collects magnetic field data from the magnetometer 132. The collection of magnetic field data may be performed in background mode without any interrupting normal work of a user. The magnetometer 132 may be switched always on, so no additional efforts for this are needed.

The CPU 136 or the server 125 may analyze the magnetic field data to determine whether the wipers 126 are in operation at the current time. Even one wiper cycle may produce noticeable spike in magnetometer signal, which may be even more easily visible in the frequency domain. While spikes may be visibly apparent when the data is plotted, the CPU 136 may identify the spikes through an algorithm for detecting spikes.

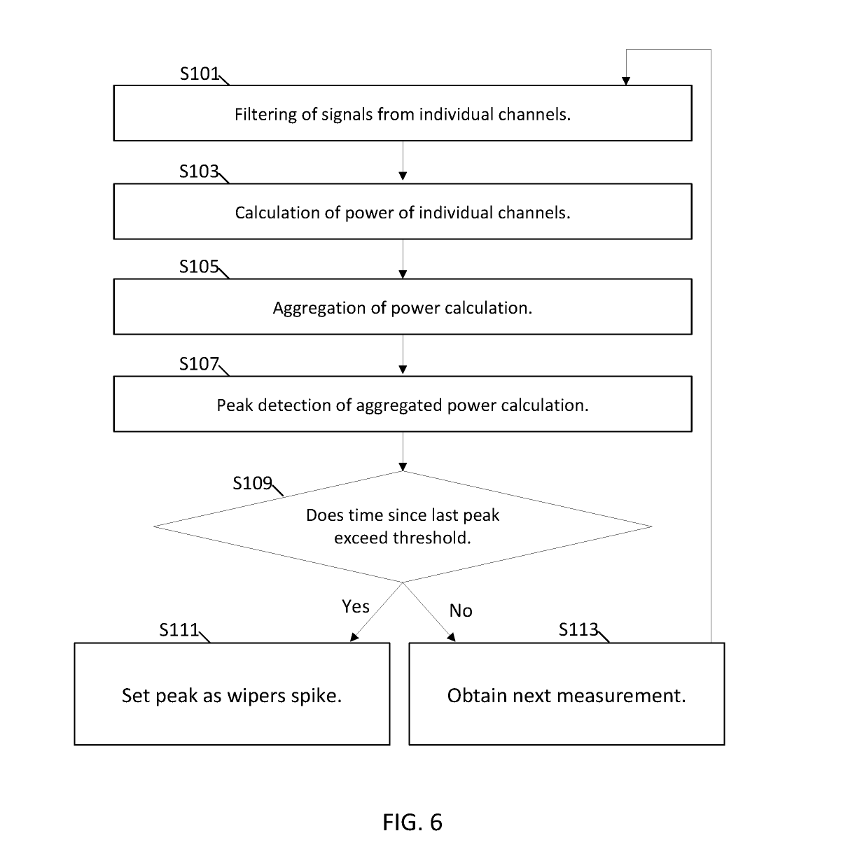

FIG. 6 illustrates an example flowchart for detecting wiper spikes in sensor data. The acts of the flowchart may be performed by CPU 136 or by server 125. The acts may be performed in a different order and one or more of the acts may be omitted.

At act S101, the signals from the magnetometer 132 are filtered. The magnetometer 132 may include multiple channels (e.g., X-axis channel, Y-axis channel, and Z-axis channel). The spikes could be pronounced in different channels depending on orientation of the magnetometer 132. Each of the channels is filtered independently of one another. The filtering may remove outliers (e.g., highest 5% of data and lowest 5% of data). The filtering may include a bandpass filter or a low pass filter. One example of a filter is a Butterworth filter, which may be defined by a lower limit of the bandpass, an upper limit of the bandpass, and an order. The order denotes the number of poles in the frequency response of the filter and is generally proportional to the circuit required to construct the filter. One suitable example for filtering the output of the magnetometer is a lower limit of 0.5 Hertz and an upper limit of 5 Hertz, which can be achieved by a fourth order Butterworth filter.

Power of band-pass filtered magnetometer signals significantly increases during wipers spike. At act S103, the short-term power of the individual filtered signals is calculated. The short-term power is calculated by squaring the signal and subsequent filtering using moving average within time windows (e.g., 0.5 seconds). Other short-term power calculation approaches could be used. If bandwidth of filtered magnetometer signal is narrow enough, nonlinear Teager-Kaiser energy operator (instantaneous difference between squared first derivative of the signal and product of signal itself and its second derivative) may provide better estimates of the short-term power. Alternatively acts S101 and S103 may be performed by calculating FFT of the signal, and summing squared amplitudes of FFT coefficients of interest.

At act S105, the power calculates are aggregated. In one example, the power level in the X-direction, power level in the Y-direction, and power level in the Z-direction are combined to create an aggregate power indicator value having a magnitude and a direction. Aggregation may be performed by multiplication of the individual channel powers. The magnitude of the aggregate power indicator vector may be compared to one or more threshold levels in order to identify peaks in the magnetic field that represent the motion of the wipers 126.

In order to prevent chattering and false peak detection due to power fluctuation hysteresis based peak detection (with lower and higher power thresholds) is utilized. In one example, at act S107, peak detection is started if the aggregated power (e.g., aggregate power indicator value) has crossed up a higher power threshold, the next peak detection is enabled only after the aggregated power has crossed down a lower power threshold. The lower power threshold may be a predetermined percentage (e.g., 90%) of the higher power threshold.

Another necessary condition for peak to be marked as wipers spike is that time since last peak should exceed some cycle threshold (determined by duration of one cycle of wipers working with maximum speed). A timer is started when the aggregate power indicator value passes the lower power threshold and stopped when the aggregate power indicator value passes the higher power threshold. At act S109, the duration of the timer is compared to a cycle threshold. Examples for the cycle threshold include 500 milliseconds, 1 second, and 2 seconds. If the duration exceeds the cycle threshold, the algorithm proceeds to designate the peak as a wipers spike at act S111. For example, the CPU 136 may record a wiper detection at the time of the time window. If the duration is less that the cycle threshold, the algorithm obtains additional measurements at S113, which may involve returning to repeat the earlier acts. Other filters and algorithm parameters may be used as well.

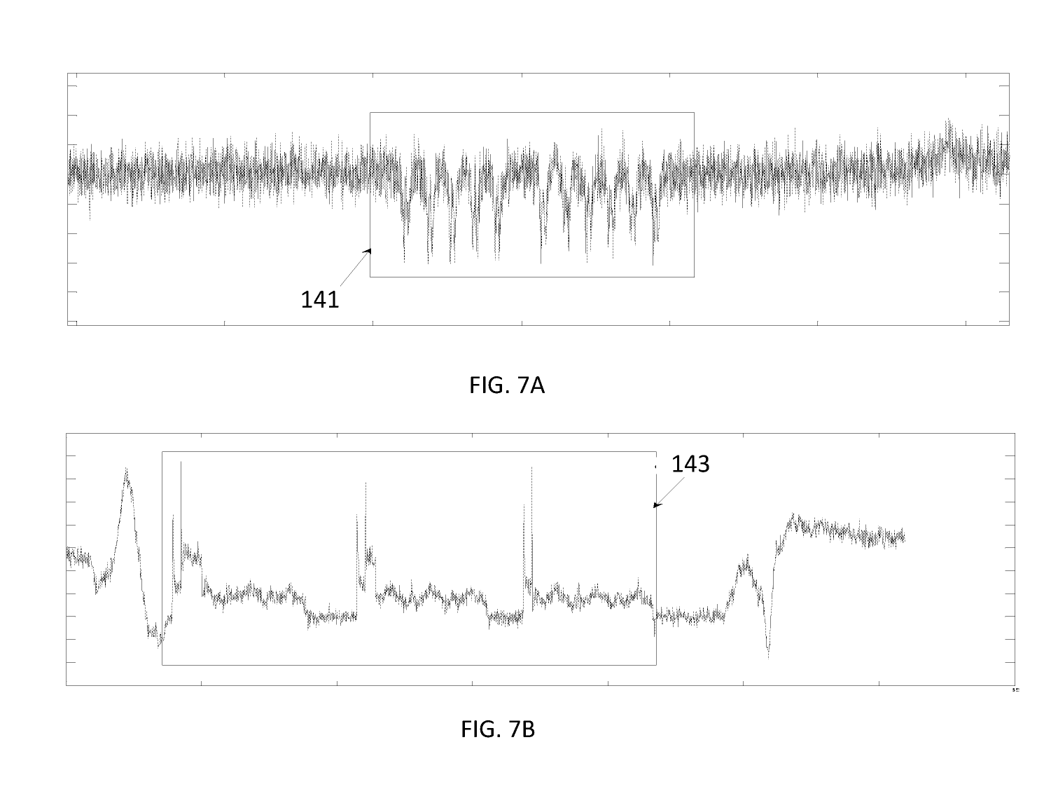

FIGS. 7A and 7B illustrate example magnetic field data. The vertical axes represent the magnetic field strength (e.g., in Tesla or gauss). The horizontal axes represent time. Different types of vehicles, different types of windshield wipers, and different types of windshield wiper motors may affect the magnetic field strength in different ways. The magnetic field data 141 and the magnetic field data 143 illustrate different types of responses from windshield wipers. In one example, the two charts represent the same type of wipers but as detected by different types of magnetometers or different types of mobile device. For example, different smartphone manufacturers may package and filter the magnetic field data in different ways as it is made available to a mobile application running on the smartphone.

In another example, the two charts may represent the same type of magnetometer and smartphone placed in different distances from the motor of the windshield wipers. The magnitude of the magnetic field may vary inversely proportionally or inversely squared, to the distance between the magnetometer to the motor. The CPU 136 may be configured to calculate a baseline based on the orientation and/or distance of the magnetometer with respect to the motor of the windshield wiper. The magnitude of the magnetic field may also depend on the orientation of the magnetometer with respect to the motor.

In another example, the two charts may represent different types of vehicles. The magnetic field data 141 may represent one type of vehicle that produced tightly spaced spikes that protrude in the negative direction, and the magnetic field data 143 may represent another type of vehicle that produced more spaced spikes that protrude in the positive direction. In another example, magnetic field data 141 represents a high speed for the motor and magnetic field data 143 may represent a low speed for the same motor. The magnetic field data may also show an intermittent speed including a cycle of a series of one, two, or three spikes followed by a period of no spikes.

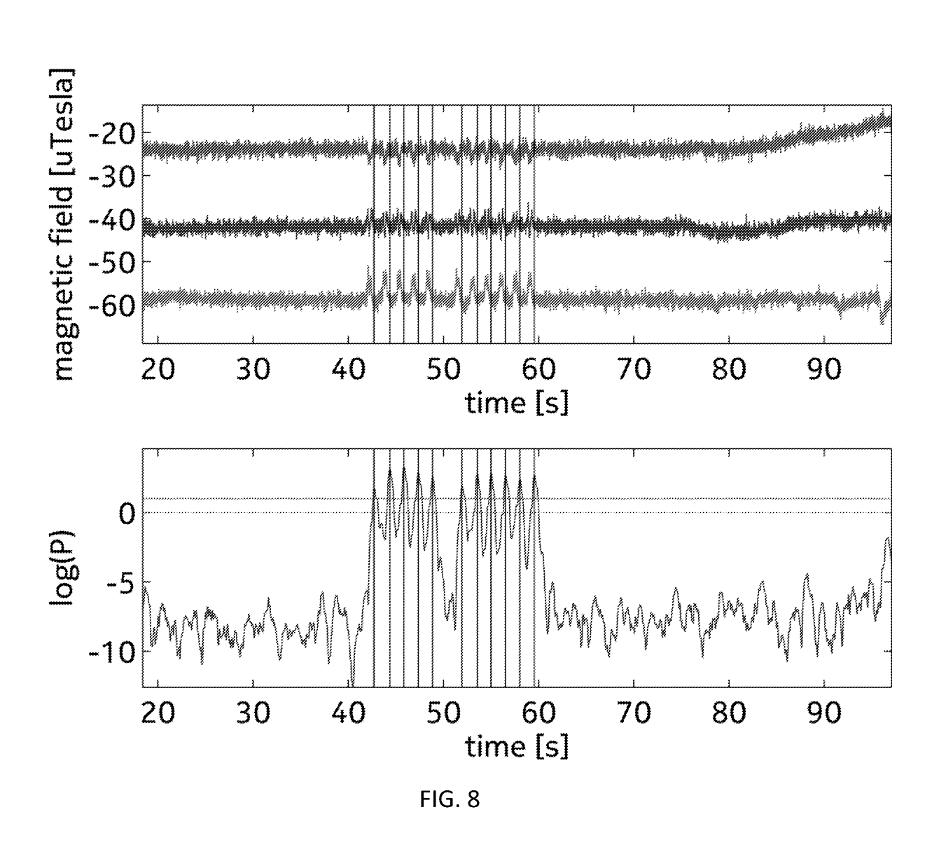

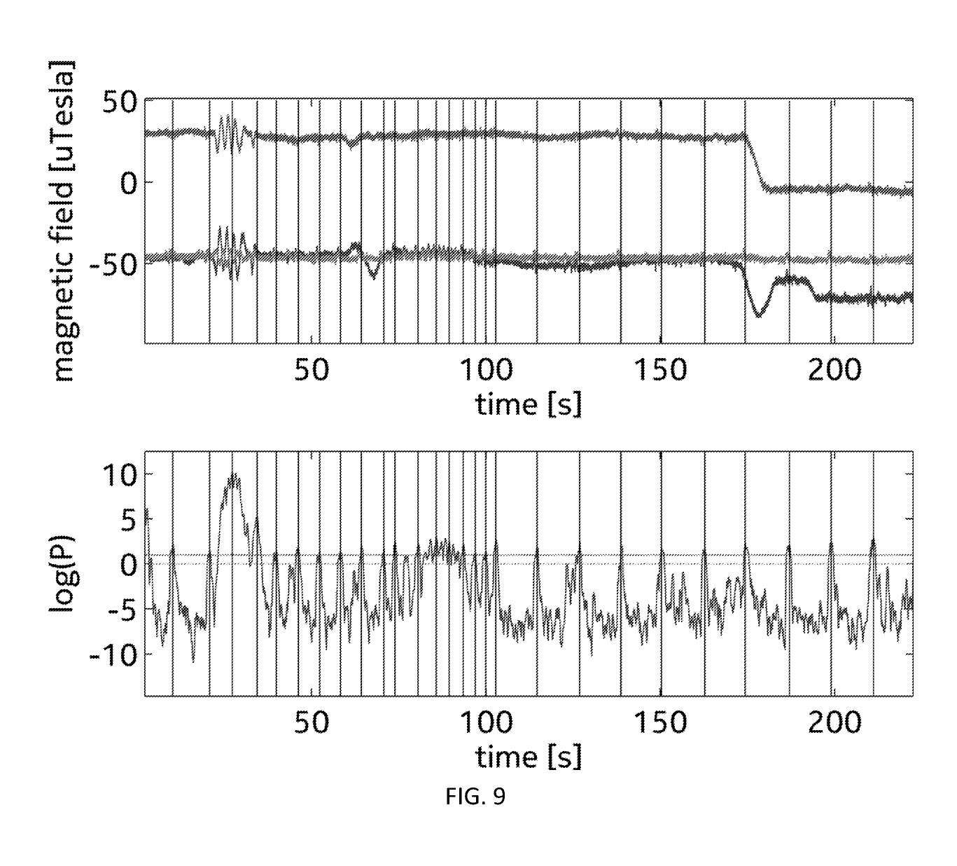

FIGS. 8 and 9 illustrate example magnetic field data for multiple axes. The magnetic field data is shown for three channels (e.g., X, Y, and Z). The log of the power of the signals illustrates the ease of identifying power spikes on a logarithmic scale. FIG. 8 illustrates a clear on and off response in the magnetic field. FIG. 9 illustrates that operators of some vehicles may turn on the wipers with varying intensity as rain begins and eventually settle into a specific speed with constant cycle. Other examples are possible.

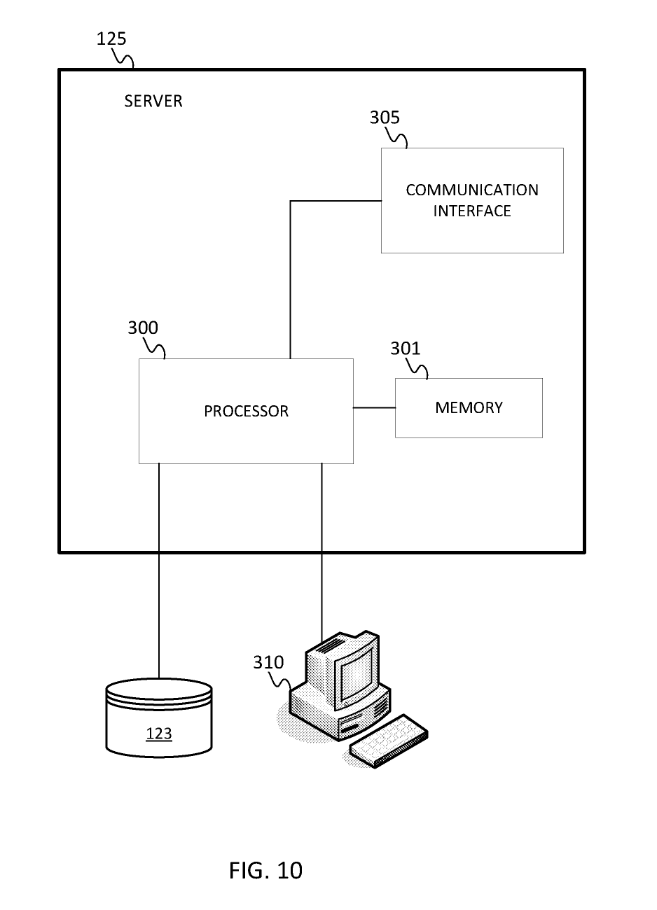

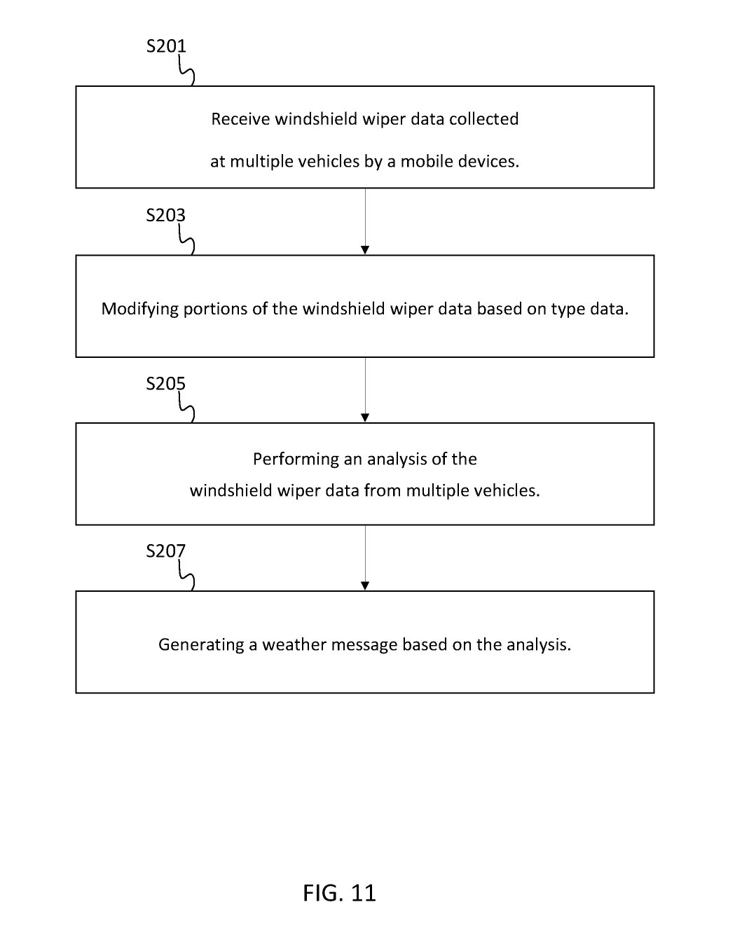

FIG. 10 illustrates an exemplary server 125 of the system of FIG. 1. The server 125 includes a processor 300, a communication interface 305, and a memory 301. The server 125 may be coupled to a database 123 and a workstation 310. The workstation 310 may be used as an input device for the server 125. In addition, the communication interface 305 is an input device for the server 125. The communication interface 305 receives data indicative of user inputs made via the workstation 128 or the mobile device 122. Additional, different, or fewer components may be included. FIG. 11 illustrates an example flowchart for providing weather data based on windshield wipers. The acts of FIG. 11 may be performed by the server 125 or another device. Additional, different, or fewer acts may be provided.

At act S201, the processor 300 or the communication interface 305 receives windshield wiper data collected at multiple vehicles by magnetic sensors of mobile devices. Information is transmitted via a mobile connection to the server 125. The server 125 accumulates information from multiple sources. In addition, information on the geographical location of the mobile device may be received. The location may be determined from a GPS sensor or approximated coordinates calculated via signal strength of available cellular towers. In case of absence of GPS coordinates from particular user, that particular user's coordinates can be recovered by the degree of similarity of information about available cell towers from the particular user with no GPS and from other users.

In many examples, each vehicle includes a single mobile device and magnetic sensor. In other examples, some vehicles (e.g., with multiple people) may include multiple mobile devices. The data from multiple mobile devices in the same vehicle may be average or otherwise manipulated to represent a single data point. For example, some mobile devices may be ignored if they are located within a predetermined distance (e.g., 3 feet or 5 feet) to another mobile device. Alternatively, the system may treat the multiple mobile device in the same vehicle the same as if the mobile devices were in different vehicles.

At act S203, the processor 300 modifies portions of the windshield wiper data based on type data. The type data allows the processor 300 to account for differences between the different probes. The type data may include any combination of a type of vehicle that produced the magnetic field, a type of windshield wiper motor that produced the magnetic field, or a type of mobile device that collected the windshield wiper data. Act 5203 is optional and may be omitted completely.

At act S205, the processor 300 performs an analysis of the windshield wiper data from multiple vehicles. The analysis may involve comparing the windshield wiper data to one or more threshold value. An initial threshold value may be associated with an OFF mode for the windshield wipers. A low threshold value may be associated with an intermitted mode for the windshield wipers. A medium threshold value may be associated with a medium speed mode for the windshield wipers. A high threshold value may be associated with a high speed mode for the windshield wipers. In addition or in the alternative to rain, the speed of the windshield wipers may estimate the degree of contamination of the road. Example contaminations include puddles, water filed pot holes, mud, snow, or slush.

At act S207, the processor 300 generates a weather message based on the analysis. The weather message may indicate that other drivers ahead are using their windshield wipers. The weather message may indicate that a statistical significant portion of drivers on a particular stretch of road are using their windshield wipers. The weather message may indicate an average or median speed of the windshield wipers (e.g., OFF, intermittent, medium, or high). The weather message may include a map based on locations of the multiple mobile devices. The map may graphically indicate individual path segments experiencing rain based on the windshield wiper data.

While windshield wipers are discussed in detail, other weather related devices may be detected using the magnetic sensor or other sensors such as humidity and temperature sensors. Examples include a defroster, in which the current flowing through defroster wires impacts a magnetic field, or a fan for an air conditioner or a heater, in which the fan changes the barometric pressure in the vehicle or the movement of the fan motor impacts a magnetic field.

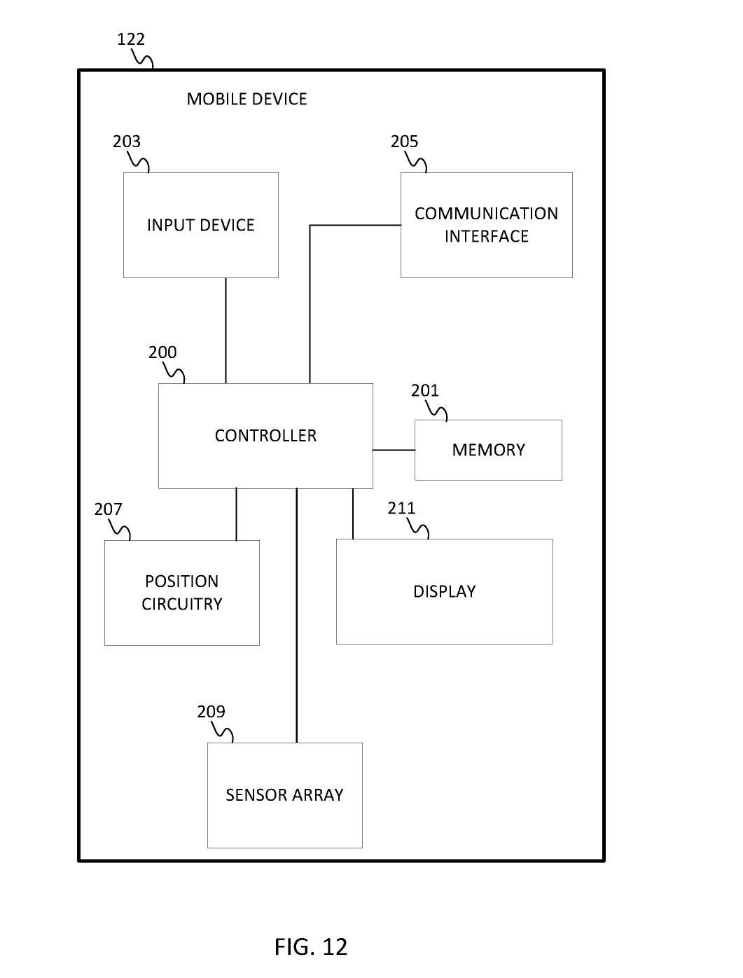

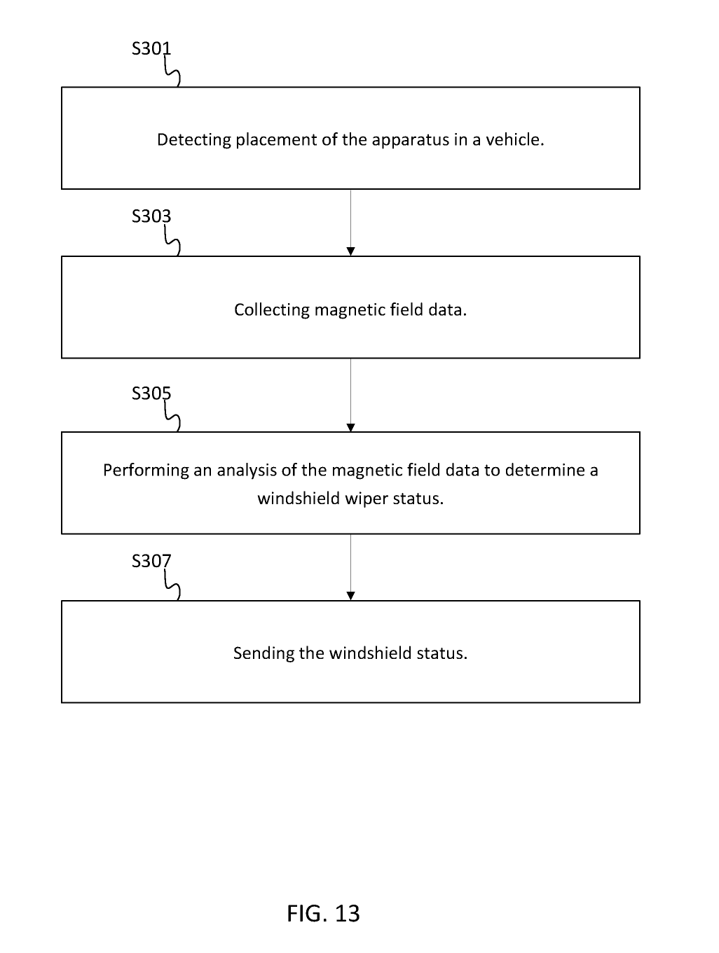

FIG. 12 illustrates an exemplary mobile device 122 of the system of FIG. 1. The mobile device 122 may be referred to as a navigation device. The mobile device 122 includes a controller 200, a memory 201, an input device 203, a communication interface 205, position circuitry 207, a sensor array 209, and a display 211. The workstation 128 may include at least a memory and processor and may be substituted for the mobile device in the following. FIG. 13 an example flowchart for providing weather data based on windshield wipers. The acts of FIG. 13 may be performed by the mobile device 122 or another device. Additional, different, or fewer acts may be provided.

At act S301, the controller 200 detects placement of the mobile device 122 in a vehicle. The placement may be determined based on the speed of the mobile device 122 calculated based one the rate of change of location data generated by the position circuitry 207. The placement may be determined based a comparison of inertial data collected by the sensor array 209 to a history of past movements that are associated with embarqueing a vehicle. The placement may be based on an input via input device 203 in which the user indicates that he is driving or riding in a vehicle. The placement may be inferred from the execution of a navigation application or other mobile application applicable to traveling in a vehicle. The placement may be based on the detection of an ignition system, an advanced driving and safety system (ADAS), or an autonomous vehicle computer. The sensor array 209 may be inside the mobile device 122, external to the mobile device 122, or included in peripherals connected to the mobile device 122.

At act S303, the controller 200 or the sensor array 209 collects magnetic field data. At act S305, the controller 200 performs an analysis of the magnetic field data to determine a windshield wiper status. As described above, the magnetic field data may be dependent on a variety of factors including the orientation of the mobile device, the placement of the mobile device, the materials of the vehicle, the type of windshield wiper motors, and the speed of the windshield wiper motors.

At act S307, the controller 200 or the communication interface 205 sends the windshield wiper status to an external device. The external device may be the server 125. In other examples, the external device is another mobile device. For example, mobile devices may exchange windshield wiper status directly. In another example, the mobile devices may post or advertise windshield wiper statuses and locations via a social networking service or other mobile application to their contacts. The mobile devices of the contacts may download the windshield wiper statuses and locations to be used in routing or displayed on a map. The controller 200 may directly identify a weather condition based on the windshield wiper data.

Either of controller 200 or processor 300 may be configured to generate a route between an origin and a dictation or modify a route based on the windshield wiper data. That is, a navigation application may be configured to avoid, or assign higher costs, to path segments associated with rain or currently report windshield wiper data above a specific level. The navigation application may be configured to compute an additional travel time based on the windshield wiper data (traffic moves slower in the rain). In addition, the reports of windshield wiper data along with subsequent traffic data may be used to build a database of the relationship between windshield wiper speed and traffic speed. Windshield wiper data for one path segment may be used to predict traffic speeds in the future in adjacent path segments in the direction of the weather pattern.

In addition or the alternative to weather reporting, the windshield wiper data may be used to provide functions for an autonomous vehicle. An autonomous vehicle is self-driving and may be referred to as a robot vehicle or an automated vehicle. The autonomous vehicle may include passengers but no driver is necessary. The mobile device 122 or another computer system in communication with the mobile device 122 may include instructions for routing the vehicle or operating the vehicle. An estimated travel time may be calculated based on the windshield wiper data and a route may be chosen based on the estimated travel time. The computing system may generate driving commands for steering the vehicle, shifting gears, increasing and decreasing the throttle, and braking as a function of the windshield wiper data because less abrupt movements and slower driving is preferred in the rain. The computing system may generate auxiliary commands for controlling the headlights, turn signals, windshield wipers, defrost, or other auxiliary functions not directly related to the movement of the vehicle. For example, the headlights may be turned on for the vehicle that collected the windshield wiper data based on the windshield wiper data. Alternatively, the headlights may be turned on for vehicles approaching the locations of the windshield wiper data.

The autonomous vehicle may include sensors for identifying the surrounding and location of the car. The sensors may include GPS, light detection and ranging (LIDAR), radar, and cameras for computer vision. Proximity sensors may aid in parking the vehicle. The proximity sensors may detect the curb or adjacent vehicles. The autonomous vehicle may optically track and follow lane markings or guide markings on the road.

The database 123 may store or maintain geographic data such as, for example, road segment or link data records and node data records. The database 123 may be supplemented by the windshield wiper data. The link data records are links or segments representing the roads, streets, or paths. The node data records are end points (e.g., intersections) corresponding to the respective links or segments of the road segment data records. The road link data records and the node data records may represent, for example, road networks used by vehicles, cars, and/or other entities. The road link data records may be associated with attributes of or about the roads such as, for example, geographic coordinates, street names, address ranges, speed limits, turn restrictions at intersections, and/or other navigation related attributes (e.g., one or more of the road segments is part of a highway or tollway, the location of stop signs and/or stoplights along the road segments), as well as points of interest (POIs), such as gasoline stations, hotels, restaurants, museums, stadiums, offices, automobile dealerships, auto repair shops, buildings, stores, parks, etc. The node data records may be associated with attributes (e.g., about the intersections) such as, for example, geographic coordinates, street names, address ranges, speed limits, turn restrictions at intersections, and other navigation related attributes, as well as POIs such as, for example, gasoline stations, hotels, restaurants, museums, stadiums, offices, automobile dealerships, auto repair shops, buildings, stores, parks, etc. The geographic data may additionally or alternatively include other data records such as, for example, POI data records, topographical data records, cartographic data records, routing data, and maneuver data.

The databases 123 may be maintained by one or more map developers (e.g., the first company and/or the second company). A map developer collects geographic data to generate and enhance the database. There are different ways used by the map developer to collect data. These ways include obtaining data from other sources such as municipalities or respective geographic authorities. In addition, the map developer may employ field personnel (e.g., the employees at the first company and/or the second company) to travel by vehicle along roads throughout the geographic region to observe features and/or record information about the features. Also, remote sensing such as, for example, aerial or satellite photography may be used.

The database 123 may be master geographic databases stored in a format that facilitates updating, maintenance, and development. For example, a master geographic database or data in the master geographic database is in an Oracle spatial format or other spatial format, such as for development or production purposes. The Oracle spatial format or development/production database may be compiled into a delivery format such as a geographic data file (GDF) format. The data in the production and/or delivery formats may be compiled or further compiled to form geographic database products or databases that may be used in end user navigation devices or systems.

For example, geographic data is compiled (such as into a physical storage format (PSF) format) to organize and/or configure the data for performing navigation-related functions and/or services, such as route calculation, route guidance, map display, speed calculation, distance and travel time functions, and other functions, by a navigation device. The navigation-related functions may correspond to vehicle navigation, pedestrian navigation, or other types of navigation. The compilation to produce the end user databases may be performed by a party or entity separate from the map developer. For example, a customer of the map developer, such as a navigation device developer or other end user device developer, may perform compilation on a received geographic database in a delivery format to produce one or more compiled navigation databases.

The input device 203 may be one or more buttons, keypad, keyboard, mouse, stylus pen, trackball, rocker switch, touch pad, voice recognition circuit, or other device or component for inputting data to the mobile device 122. The input device 203 and the display 211 may be combined as a touch screen, which may be capacitive or resistive. The display 211 may be a liquid crystal display (LCD) panel, light emitting diode (LED) screen, thin film transistor screen, or another type of display.

The positioning circuitry 207 is optional and may be excluded for the map-related functions. The positioning circuitry 207 may include GPS, Global Navigation Satellite System (GLONASS), or a cellular or similar position sensor for providing location data. The positioning system may utilize GPS-type technology, a dead reckoning-type system, cellular location, or combinations of these or other systems. The positioning circuitry 207 may include suitable sensing devices that measure the traveling distance, speed, direction, and so on, of the mobile device 122. The positioning system may also include a receiver and correlation chip to obtain a GPS signal. Alternatively or additionally, the one or more detectors or sensors may include an accelerometer built or embedded into or within the interior of the mobile device 122. The accelerometer is operable to detect, recognize, or measure the rate of change of translational and/or rotational movement of the mobile device 122. The mobile device 122 receives location data from the positioning system. The location data indicates the location of the mobile device 122.

The controller 200 and/or processor 300 may include a general processor, digital signal processor, an application specific integrated circuit (ASIC), field programmable gate array (FPGA), analog circuit, digital circuit, combinations thereof, or other now known or later developed processor. The controller 200 and/or processor 300 may be a single device or combinations of devices, such as associated with a network, distributed processing, or cloud computing.

The memory 201 and/or memory 301 may be a volatile memory or a non-volatile memory. The memory 201 and/or memory 301may include one or more of a read only memory (ROM), random access memory (RAM), a flash memory, an electronic erasable program read only memory (EEPROM), or other type of memory. The memory 201 and/or memory 301 may be removable from the mobile device 100, such as a secure digital (SD) memory card.

The communication interface 205 and/or communication interface 305 may include any operable connection. An operable connection may be one in which signals, physical communications, and/or logical communications may be sent and/or received. An operable connection may include a physical interface, an electrical interface, and/or a data interface. The communication interface 205 and/or communication interface 305 provides for wireless and/or wired communications in any now known or later developed format.

The network 127 may include wired networks, wireless networks, or combinations thereof. The wireless network may be a cellular telephone network, an 802.11, 802.16, 802.20, or WiMax network. Further, the network 127 may be a public network, such as the Internet, a private network, such as an intranet, or combinations thereof, and may utilize a variety of networking protocols now available or later developed including, but not limited to TCP/IP based networking protocols.

While the non-transitory computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

Although the present specification describes components and functions that may be implemented in particular embodiments with reference to particular standards and protocols, the invention is not limited to such standards and protocols. For example, standards for Internet and other packet switched network transmission (e.g., TCP/IP, UDP/IP, HTML, HTTP, HTTPS) represent examples of the state of the art. Such standards are periodically superseded by faster or more efficient equivalents having essentially the same functions. Accordingly, replacement standards and protocols having the same or similar functions as those disclosed herein are considered equivalents thereof.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

As used in this application, the term ‘circuitry’ or ‘circuit’ refers to all of the following: (a) hardware-only circuit implementations (such as implementations in only analog and/or digital circuitry) and (b) to combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and (c) to circuits, such as a microprocessor(s) or a portion of a microprocessor(s), that require software or firmware for operation, even if the software or firmware is not physically present.

This definition of ‘circuitry’ applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in server, a cellular network device, or other network device.

Processors suitable for the execution of a computer program include, by way of example, both general and special purpose microprocessors, and anyone or more processors of any kind of digital computer. Generally, a processor receives instructions and data from a read only memory or a random access memory or both. The essential elements of a computer are a processor for performing instructions and one or more memory devices for storing instructions and data. Generally, a computer also includes, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio player, a Global Positioning System (GPS) receiver, to name just a few. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a device having a display, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized Accordingly, the disclosure and the figures are to be regarded as illustrative rather than restrictive.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings and described herein in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, are apparent to those of skill in the art upon reviewing the description.

The Abstract of the Disclosure is provided to comply with 37 C.F.R. §1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

It is intended that the foregoing detailed description be regarded as illustrative rather than limiting and that it is understood that the following claims including all equivalents are intended to define the scope of the invention. The claims should not be read as limited to the described order or elements unless stated to that effect. Therefore, all embodiments that come within the scope and spirit of the following claims and equivalents thereto are claimed as the invention.

1-20. (canceled)

21. A method comprising:
receiving windshield wiper data collected by at least one magnetic sensor of at least one mobile device;
performing, at a processor, an analysis of the windshield wiper data; and
generating a weather message based on the analysis.

22. The method of claim 21, wherein the windshield wiper data describes a magnetic field caused by one or more windshield wipers.

23. The method of claim 21, wherein the magnetic field is caused by a motor for one or more windshield wipers.

24. The method of claim 21, wherein the windshield wiper data is based on output from a magnetometer.

25. The method of claim 21, wherein the analysis includes a comparison to a threshold magnetic field value.

26. The method of claim 21, wherein the at least one mobile device includes a plurality of mobile devices.

27. The method of claim 21, further comprising:
receiving location data from the at least one mobile device, wherein the weather message includes a map based on the location data and the windshield wiper data.

28. The method of claim 27, further comprising:
sending the weather message to a requesting device, wherein the requesting device is different from the at least one mobile device.

29. An apparatus comprising:
at least one processor; and
at least one memory including computer program code for one or more programs; the at least one memory and the computer program code configured to, with the at least one processor, cause the apparatus to at least perform:
detecting placement of the apparatus in a vehicle;
collecting magnetic field data; and
performing an analysis of the magnetic field data to determine a windshield wiper status.

30. The apparatus of claim 29, the at least one memory and the computer program code configured to, with the at least one processor, cause the apparatus to at least perform:
identify a weather condition based on the windshield wiper status.

31. The apparatus of claim 30, wherein the windshield wiper status describes a speed of the windshield wiper, and the weather condition is a function of the speed of the windshield wiper.

32. The apparatus of claim 29, wherein the placement of the apparatus in the vehicle is based on inertial sensor data or speed data.

33. The apparatus of claim 29, wherein the analysis of the magnetic field data is based on a type of the vehicle or type of the apparatus in the vehicle.

34. The apparatus of claim 29, wherein the analysis of the magnetic field data is based on a baseline defined by previous magnetic field data.

35. A method comprising:
receiving windshield wiper data collected at multiple vehicles by a plurality of mobile devices;
performing, by a processor, an analysis of the windshield wiper data from multiple vehicles; and
generating a weather message based on the analysis.

36. The method of claim 35, wherein the windshield wiper data describes a magnetic field caused by one or more windshield wiper motors.

37. The method of claim 36, further comprising:
modifying portions of the windshield wiper data based on a type of vehicle that impacted the magnetic field, a type of windshield wiper motor that impacted the magnetic field, or a type of mobile device that collected the windshield wiper data.

38. The method of claim 37, wherein the analysis includes a comparison of the modified portions of the windshield wiper data to a threshold value.

39. The method of claim 35, wherein the weather message includes a map based on locations of the plurality of mobile devices.

40. The method of claim 39, wherein the map indicates individual path segments experiencing rain based on the windshield wiper data.
